(19) United States
(12) Patent Application Publication
(10) Pub. No.: US 2024/0199791 A1
(43) Pub. Date: Jun. 20, 2024

(54) RESIN COMPOSITION AND ARTICLE MADE THEREFROM

(71) Applicant: Elite Material Co., Ltd., Taoyuan (TW)

(72) Inventors: Chun-Hung CHEN, Taoyuan City (TW); Chen-Yu HSIEH, Taoyuan City (TW)

(21) Appl. No.: 18/096,169

(22) Filed: Jan. 12, 2023

(30) Foreign Application Priority Data
Dec. 18, 2022 (TW) 111148632

(51) Int. Cl. C08G 59/24; C08G 59/30; C08G 59/42; C08J 5/18; C08J 5/24; C08K 3/28; C08K 3/38

(52) U.S. Cl. CPC C08G 59/245; C08G 59/308; C08G 59/4223; C08J 5/18; C08J 5/24; C08K 3/28; C08K 3/38; C08K 2003/282; C08K 2003/385; C08K 2201/005

(57) ABSTRACT

A resin composition includes: (A) 100 parts by weight of an epoxy resin; (B) 10 to 30 parts by weight of a phenoxy resin; (C) 30 to 50 parts by weight of hydrogenated trimellitic anhydride; and (D) 250 to 400 parts by weight of a co-sintered body of aluminum nitride and boron nitride. The resin composition may be used to make a prepreg, a resin film, a laminate or a printed circuit board, and at least one of the following properties can be improved, including visible light reflectivity, routing distance, flame retardancy and copper foil peeling strength.

### CROSS-REFERENCE TO RELATED APPLICATION

This application claims the priority benefits of Taiwan Patent Application No. 111148632, filed on Dec. 18, 2022. The entirety the above-mentioned patent application is hereby incorporated by reference herein and made a part of this specification.

### BACKGROUND

### 1. Field of the Disclosure

The present disclosure relates to a resin composition and more particularly to a resin composition useful for preparing a prepreg, a resin film, a laminate or a printed circuit board.

### 2. Description of Related Art

For electronic materials such as printed circuit boards, in order to improve the thermal conductivity of the insulation layer of a laminate, aluminum oxide and boron nitride with advantages such as high thermal conductivity and low thermal impedance are usually added, but higher content of boron nitride will decrease the copper foil peeling strength, and higher content of aluminum oxide will reduce the processability of the laminate. Therefore, there is a need for developing materials suitable for a high performance laminate. To overcome the aforesaid problems, the present disclosure provides a resin composition which may maintain high thermal conductivity, low thermal impedance and high copper foil peeling strength, while improving the processability of the laminate (such as routing distance) and further improving the flame retardancy.

### SUMMARY

To overcome the problems of prior arts, particularly one or more above-mentioned technical problems facing conventional materials, it is a primary object of the present disclosure to provide a resin composition and an article made therefrom which may overcome at least one of the above-mentioned technical problems.

To achieve the above-mentioned objects, the present disclosure provides a resin composition, comprising: (A) 100 parts by weight of an epoxy resin: (B) 10 to 30 parts by weight of a phenoxy resin: (C) 30 to 50 parts by weight of hydrogenated trimellitic anhydride: and (D) 250 to 400 parts by weight of a co-sintered body of aluminum nitride and boron nitride.

For example, in one embodiment, the epoxy resin comprises bisphenol A epoxy resin (such as but not limited to bisphenol A novolac epoxy resin), triphenylmethane epoxy resin, biphenyl epoxy resin, alicyclic epoxy resin or a combination thereof.

For example, in one embodiment, the phenoxy resin comprises bisphenol A-based phenoxy resin, fluorene-based phenoxy resin or a combination thereof.

For example, in one embodiment, the weight ratio of aluminum nitride to boron nitride in the co-sintered body of aluminum nitride and boron nitride is 6:1 to 14:1.

For example, in one embodiment, the co-sintered body of aluminum nitride and boron nitride has a particle size distribution (D50) of 20 μm to 40 μm.

For example, in one embodiment, the resin composition further comprises curing accelerator, flame retardant, polymerization inhibitor, solvent, silane coupling agent, coloring agent, toughening agent or a combination thereof.

Another main object of the present disclosure is to provide an article made from the aforesaid resin composition, comprising a prepreg, a resin film, a laminate or a printed circuit board.

For example, in one embodiment, articles made from the resin composition disclosed herein have one, more or all of the following properties:
a visible light reflectivity of greater than or equal to 81%;
a routing distance of greater than or equal to 292 cm;
a flame retardancy of V-O as measured by reference to UL 94; and
a copper foil peeling strength as measured by reference to IPC-TM-650 2.4.8 of greater than or equal to 4.89 lb/in.

### DESCRIPTION OF THE EMBODIMENTS

To enable those skilled in the art to further appreciate the features and effects of the present disclosure, words and terms contained in the specification and appended claims are described and defined. Unless otherwise defined, all technical and scientific terms used herein have the same meaning as commonly understood by those of ordinary skill in the art to which this disclosure pertains. In the case of conflict, the present document and definitions contained herein will control.

While some theories or mechanisms may be proposed herein, the present disclosure is not bound by any theories or mechanisms described regardless of whether they are right or wrong, as long as the embodiments can be implemented according to the present disclosure.

As used herein, “a,” “an” or any similar expression is employed to describe components and features of the present disclosure. This is done merely for convenience and to give a general sense of the scope of the present disclosure. Accordingly, this description should be read to include one or at least one and the singular also includes the plural unless it is obvious to mean otherwise.

As used herein, “or a combination thereof” means “or any combination thereof”, and “any” means “any one”, vice versa.

As used herein, the term “comprises,” “comprising,” “includes,” “including,” “encompass,” “encompassing,” “has,” “having” or any other variant thereof is construed as an open-ended transitional phrase intended to cover a non-exclusive inclusion. For example, a composition or article of manufacture that comprises a list of elements is not necessarily limited to only those elements but may include other elements not expressly listed but inherent to such composition or article of manufacture. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present). In addition, whenever open-ended transitional phrases are used, such as “comprises,” “comprising,” “includes,” “including,” “encompass,” “encompassing,” “has,” “having” or any other variant thereof, it is understood that close-ended transitional phrases such as “consisting of,” “composed by” and “remainder being” and partially open-ended transitional phrases such as “consisting essentially of,” “primarily consisting of,” “mainly consisting of,” “primarily containing,” “composed essentially of,” “essentially having,” etc. are also disclosed and included.

In this disclosure, features and conditions such as values, numbers, contents, amounts or concentrations are presented as a numerical range or a percentage range merely for convenience and brevity. Therefore, a numerical range or a percentage range should be interpreted as encompassing and specifically disclosing all possible subranges and individual numerals or values therein, including integers and fractions, particularly all integers therein. For example, a range of “1.0 to 8.0” or “between 1.0 and 8.0” should be understood as explicitly disclosing all subranges such as 1.0 to 8.0, 1.0 to 7.0, 2.0 to 8.0, 2.0 to 6.0, 3.0 to 6.0, 4.0 to 8.0, 3.0 to 8.0 and so on and encompassing the endpoint values, particularly subranges defined by integers, as well as disclosing all individual values in the range such as 1.0, 2.0, 3.0, 4.0, 5.0, 6.0, 7.0 and 8.0. Unless otherwise defined, the aforesaid interpretation rule should be applied throughout the present disclosure regardless of broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits. For example, 40.0 should be understood as covering a range of 39.50 to 40.49.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X₁, X₂ and X₃,” it is intended to disclose the situations of X is X₁ and X is X₁ and/or X₂ and/or X₃. In addition, when a Markush group or a list of items is used to describe examples or embodiments of the present disclosure, a skilled artisan will understand that any subgroup or any combination of the members or items in the Markush group or list may also be used to describe the present disclosure. Therefore, for example, when X is described as being “selected from a group consisting of X₁, X₂ and X₃” and Y is described as being “selected from a group consisting of Y₁, Y₂ and Y₃,” the disclosure shall be interpreted as any combination of X is X₁ or X₂ or X₃ and Y is Y₁ or Y₂ or Y₃.

Unless otherwise specified, according to the present disclosure, a compound refers to a chemical substance formed by two or more elements bonded with chemical bonds and may comprise a small molecule compound and a polymer compound, but not limited thereto. Any compound disclosed herein is interpreted to not only include a single chemical substance but also include a class of chemical substances having the same kind of components or having the same property. In addition, as used herein, a mixture refers to a combination of two or more compounds.

Unless otherwise specified, according to the present disclosure, a polymer refers to the product formed by monomer(s) via polymerization and usually comprises multiple aggregates of polymers respectively formed by multiple repeated simple structure units by covalent bonds: the monomer refers to the compound forming the polymer. A polymer may comprise a homopolymer, a copolymer, a prepolymer, etc., but not limited thereto. A prepolymer refers to a polymer having a lower molecular weight between the molecular weight of monomer and the molecular weight of final polymer. The term “polymer” includes but is not limited to an oligomer. An oligomer refers to a polymer with 2-20, typically 2-5, repeating units. For example, the term “diene polymer” as used herein is construed as comprising diene homopolymer, diene copolymer, diene prepolymer and diene oligomer.

Unless otherwise specified, the term “resin” is a widely used common name of a synthetic polymer and is construed in the present disclosure as comprising monomer and its combination, polymer and its combination or a combination of monomer and its polymer, but not limited thereto.

Unless otherwise specified, according to the present disclosure, a modification comprises a product derived from a resin with its reactive functional group modified, a product derived from a prepolymerization reaction of a resin and other resins, a product derived from a crosslinking reaction of a resin and other resins, a product derived from homopolymerizing a resin, a product derived from copolymerizing a resin and other resins, etc.

Unless otherwise specified, according to the present disclosure, when the term acrylate or acrylonitrile is expressed as (meth)acrylate or (meth)acrylonitrile, it is intended to comprise both situations of containing and not containing a methyl group; for example, poly(meth)acrylate is construed as including polyacrylate and polymethacrylate. For example, (meth)acrylonitrile is construed as including acrylonitrile and methacrylonitrile.

Unless otherwise specified, an alkyl group and an alkenyl group described herein are construed to encompass various isomers thereof. For example, a propyl group is construed to encompass n-propyl and iso-propyl.

It should be understood that all features disclosed herein may be combined in any way to constitute the solution of the present disclosure, as long as there is no conflict present in the combination of these features.

Unless otherwise specified, as used herein, part(s) by weight represents weight part(s) in any weight unit, such as but not limited to kilogram, gram, pound and so on. For example, 100 parts by weight of the epoxy resin may represent 100 kilograms of the epoxy resin or 100 pounds of the epoxy resin. If a resinous solution comprises solvent and resin, the part by weight of (solid or liquid) resin generally refers to the weight unit of the (solid or liquid) resin, not including the weight unit of the solvent in the solution, and the part by weight of the solvent refers to the weight unit of the solvent.

The following embodiments and examples are illustrative in nature and are not intended to limit the present disclosure and its application. In addition, the present disclosure is not bound by any theory described in the background and summary above or the following embodiments or examples. Unless otherwise specified, processes, reagents and conditions described in the examples are those known in the art.

Generally, the present disclosure provides a resin composition, comprising:
(A) 100 parts by weight of an epoxy resin;
(B) 10 to 30 parts by weight of a phenoxy resin;
(C) 30 to 50 parts by weight of hydrogenated trimellitic anhydride; and
(D) 250 to 400 parts by weight of a co-sintered body of aluminum nitride and boron nitride.

For example, in one embodiment, the epoxy resin may comprise various epoxy resins known in the art to which this disclosure pertains. The epoxy resin suitable for the present disclosure is not particularly limited and may be any one or more commercially available products, self-prepared products or a combination thereof. For example, the epoxy resin suitable for the present disclosure may comprise but not limited to any one or more of the following epoxy resins: bisphenol A epoxy resin, bisphenol F epoxy resin, bisphenol S epoxy resin, bisphenol AD epoxy resin, phenol novolac epoxy resin, trifunctional epoxy resin, tetrafunctional epoxy resin, dicyclopentadiene (DCPD) epoxy resin, biphenyl epoxy resin, phosphorus-containing epoxy resin, p-xylene epoxy resin, naphthalene epoxy resin (e.g., naphthol epoxy resin), benzofuran epoxy resin, triphenylmethane epoxy resin and alicyclic epoxy resin. The novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin or o-cresol novolac epoxy resin. For example, in one embodiment, the epoxy resin comprises bisphenol A epoxy resin (such as but not limited to bisphenol A novolac epoxy resin), triphenylmethane epoxy resin, biphenyl epoxy resin, aliphatic epoxy resin (such as but not limited to alicyclic epoxy resin) or a combination thereof.

For example, in one embodiment, the phenoxy resin may comprise various phenoxy resins known in the art to which this disclosure pertains. The phenoxy resin suitable for the present disclosure is not particularly limited and may be any one or more commercially available products, self-prepared products, or a combination thereof. For example, the phenoxy resin suitable for the present disclosure may comprise but not limited to those sold under the product name PKHA, PKHB, PKHB+, PKHC, PKHH, PKHJ, PKFE, PKHP-200 or PKHW-34 from Gabriel Performance Products, YP50S sold by Nippon Steel & Sumikin Chemical or FX-293 and FX-280 sold by Tohto Kasei Co., Ltd. For example, in one embodiment, the phenoxy resin comprises bisphenol A-based phenoxy resin, fluorene-based phenoxy resin or a combination thereof. In the present disclosure, relative to 100 parts by weight of the epoxy resin, the amount of the phenoxy resin in the resin composition may range from 10 to 30 parts by weight, such as but not limited to 10 parts by weight, 15 parts by weight, 20 parts by weight, 25 parts by weight or 30 parts by weight, but not limited thereto.

In the present disclosure, the hydrogenated trimellitic anhydride refers to a trimellitic anhydride after hydrogenation, wherein the hydrogenated trimellitic anhydride is also known as 1,2,4-benzenetricarboxylic acid anhydride. In the present disclosure, relative to 100 parts by weight of the epoxy resin, the amount of the hydrogenated trimellitic anhydride in the resin composition may range from 30 to 50 parts by weight, such as but not limited to 30 parts by weight, 35 parts by weight, 40 parts by weight, 45 parts by weight or 50 parts by weight, but not limited thereto.

In the present disclosure, the co-sintered body of aluminum nitride and boron nitride refers to a sintered body formed by aluminum nitride and boron nitride. The co-sintered body of aluminum nitride and boron nitride may be prepared according to processes and conditions as known in the art to which this disclosure pertains. For example, in one embodiment, the co-sintered body of aluminum nitride and boron nitride is prepared from aluminum nitride and boron nitride in a weight ratio of such as but not limited to 6:1 to 14:1, mixed with sintering aid such as calcium carbonate, sodium carbonate, boric acid or the like, and formed using metal molds, cold isostatic pressing (CIP) or other known processes, followed by sintering at a temperature of 1500° ° C. to 2200° C. in a non-oxidative gas atmosphere of nitrogen, argon or the like for 1 to 30 hours, so as to obtain the co-sintered body of aluminum nitride and boron nitride. The particle size distribution (D50) of the co-sintered body of aluminum nitride and boron nitride is not particularly limited and may range from 20 μm to 40 μm, but not limited thereto. In the present disclosure, for example, unless otherwise specified, the particle size distribution (D50) is the value of the particle diameter at 50% in the cumulative volume distribution of the filler, such as but not limited to a co-sintered body of aluminum nitride and boron nitride. In the present disclosure, relative to 100 parts by weight of the epoxy resin, the amount of the co-sintered body of aluminum nitride and boron nitride in the resin composition may range from 250 to 400 parts by weight, such as but not limited to 250 parts by weight, 300 parts by weight, 350 parts by weight or 400 parts by weight, but not limited thereto.

In addition, the resin composition of the present disclosure may also optionally comprise curing accelerator, flame retardant, polymerization inhibitor, solvent, silane coupling agent, coloring agent, toughening agent or a combination thereof, but not limited thereto.

For example, the curing accelerator (including curing initiator) may comprise a catalyst, such as a Lewis base or a Lewis acid. The Lewis base may comprise any one or more of imidazole, boron trifluoride-amine complex, ethyltriphenyl phosphonium chloride, 2-methylimidazole (2MI), 2-phenyl-1H-imidazole (2PZ), 2-ethyl-4-methyl imidazole (2E4MI), triphenylphosphine (TPP) and 4-dimethylaminopyridine (DMAP). The Lewis acid may comprise metal salt compounds, such as those of manganese, iron, cobalt, nickel, copper and zinc, such as zinc octanoate or cobalt octanoate. The curing accelerator also includes a curing initiator, such as a peroxide capable of producing free radicals, examples of curing initiator including but not limited to dicumyl peroxide, tert-butyl peroxybenzoate, dibenzoyl peroxide (BPO), 2,5-dimethyl-2,5-di(tert-butyl peroxy)-3-hexyne (25B), bis(tert-butylperoxyisopropyl)benzene or a combination thereof.

For example, the flame retardant used herein may be any one or more flame retardants useful for preparing a prepreg, a resin film, a laminate or a printed circuit board, examples including but not limited to a phosphorus-containing flame retardant, preferably comprising ammonium polyphosphate, hydroquinone bis-(diphenyl phosphate), bisphenol A bis-(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate) (RDXP, such as commercially available PX-200, PX-201, and PX-202), phosphazene (such as commercially available SPB-100, SPH-100, and SPV-100), melamine polyphosphate, DOPO (9,10-dihydro-9-oxa-10-phosphaphenanthrene-10-oxide) and its derivatives or resins, DPPO (diphenylphosphine oxide) and its derivatives or resins, melamine cyanurate, tri-hydroxy ethyl isocyanurate, aluminium phosphinate (e.g., commercially available OP-930 and OP-935), or a combination thereof.

For example, the flame retardant may be a DPPO compound (e.g., di-DPPO compound, such as commercially available PQ-60), a DOPO compound (e.g., di-DOPO compound), a DOPO resin (e.g., DOPO-HQ, DOPO-NQ, DOPO-PN, and DOPO-BPN) and a DOPO-containing epoxy resin, wherein DOPO-PN is a DOPO phenol novolac compound, and DOPO-BPN may be a DOPO-containing bisphenol novolac compound, such as DOPO-BPAN (DOPO-bisphenol A novolac), DOPO-BPFN (DOPO-bisphenol F novolac) or DOPO-BPSN (DOPO-bisphenol S novolac).

For example, the polymerization inhibitor may comprise, but not limited to, 1,1-diphenyl-2-picrylhydrazyl radical, methyl acrylonitrile, 2,2,6,6-tetramethyl-1-oxo-piperidine, dithioester, nitroxide-mediated radical, triphenylmethyl radical, metal ion radical, sulfur radical, hydroquinone, 4-methoxyphenol, p-benzoquinone, phenothiazine, B-phenylnaphthylamine, 4-t-butylcatechol, methylene blue, 4,4′-butylidenebis(6-t-butyl-3-methylphenol), 2,2-methylenebis(4-ethyl-6-t-butyl phenol) or a combination thereof. For example, the nitroxide-mediated radical may comprise, but not limited to, nitroxide radicals derived from cyclic hydroxylamines, such as 2,2,6,6-substituted piperidine 1-oxyl free radical, 2,2,5,5-substituted pyrrolidine 1-oxyl free radical or the like. Preferred substitutes include alkyl groups with 4 or fewer carbon atoms, such as methyl group or ethyl group. Examples of the compound containing a nitroxide radical include but are not limited to 2,2,6,6-tetramethylpiperidine 1-oxyl free radical, 2,2,6,6-tetraethylpiperidine 1-oxyl free radical, 2,2,6,6-tetramethyl-4-oxo-piperidine 1-oxyl free radical, 2,2,5,5-tetramethyl pyrrolidine 1-oxyl free radical, 1,1,3,3-tetramethyl-2-isoindoline oxygen radical, N,N-di-tert-butylamine oxygen free radical and so on. Nitroxide radicals may also be replaced by using stable radicals such as galvinoxyl radicals. The polymerization inhibitor suitable for the resin composition of the present disclosure may include products derived from the polymerization inhibitor with its hydrogen atom or group substituted by other atom or group. Examples include products derived from a polymerization inhibitor with its hydrogen atom substituted by an amino group, a hydroxyl group, a carbonyl group or the like.

For example, the solvent is not particularly limited and may be any solvent suitable for dissolving the resin composition disclosed herein, example including, but not limited to, methanol, ethanol, ethylene glycol monomethyl ether, acetone, butanone (methyl ethyl ketone), methyl isobutyl ketone, cyclohexanone, toluene, xylene, methoxyethyl acetate, ethoxyethyl acetate, propoxyethyl acetate, ethyl acetate, dimethylformamide, dimethylacetamide, propylene glycol methyl ether, or a mixture thereof.

For example, the silane coupling agent may comprise silane (such as but not limited to siloxane) and may be further categorized according to the functional groups into amino silane, epoxide silane, vinyl silane, acrylate silane, methacrylate silane, hydroxyl silane, isocyanate silane, methacryloxy silane and acryloxy silane.

For example, the coloring agent may comprise but not limited to dye or pigment.

As used herein, the purpose of adding toughening agent is to improve the toughness of the resin composition. For example, the toughening agent may comprise, but not limited to, carboxyl-terminated butadiene acrylonitrile rubber (CTBN rubber), core-shell rubber, or a combination thereof.

The resin composition of various embodiments may be processed to make different articles, such as those suitable for use as components in electronic products, including but not limited to a prepreg, a resin film, a laminate or a printed circuit board. For example, the resin compositions of various embodiments may be used to make prepregs.

For example, the prepreg disclosed herein has a reinforcement material and a layered structure formed thereon, wherein the layered structure is made by heating the resin composition at high temperature to a semi-cured state (B-stage). Suitable baking temperature for making the prepreg may be for example 60° C. to 120ºC. The reinforcement material may be a fiber material or a non-fiber material, configured as any one of woven fabric and non-woven fabric, and the woven fabric preferably comprises fiberglass fabrics. Types of fiberglass fabrics are not particularly limited and may be any commercial fiberglass fabric useful for various printed circuit boards, such as E-glass fiber fabric, D-glass fiber fabric, S-glass fiber fabric, T-glass fiber fabric, L-glass fiber fabric or Q-glass fiber fabric, wherein the fiber may comprise yarns and rovings, in spread form or standard form. Non-woven fabric preferably comprises liquid crystal polymer non-woven fabric, such as polyester non-woven fabric, polyurethane non-woven fabric and so on, but not limited thereto. Woven fabric may also comprise liquid crystal polymer woven fabric, such as polyester woven fabric, polyurethane woven fabric and so on, but not limited thereto. The reinforcement material may increase the mechanical strength of the prepreg. In one preferred embodiment, the reinforcement material can be optionally pre-treated by a silane coupling agent. The prepreg may be further heated and cured to the C-stage to form an insulation layer.

For example, by well mixing the resin composition to form a varnish, loading the varnish into an impregnation tank, impregnating a fiberglass fabric into the impregnation tank to adhere the resin composition onto the fiberglass fabric, and finally heating and baking the resin composition at a proper temperature to a semi-cured state, a prepreg may be obtained.

For example, the article made from the resin composition disclosed herein may be a resin film.

For example, in one embodiment, the resin film disclosed herein is prepared by heating and baking the resin composition to the semi-cured state (B-stage). For example, the resin composition may be selectively coated on a liquid crystal polymer film, a polyethylene terephthalate film (PET film) or a polyimide film: for example, the resin composition from each embodiment may be coated on a copper foil to uniformly adhere the resin composition thereon, followed by heating and baking at 60° C. to 120° C. for 3 to 10 minutes to a semi-cured state to form a resin film, so as to obtain a copper-clad resin film (i.e., resin coated copper).

For example, the resin compositions of various embodiments may be used to make laminates.

For example, in one embodiment, the laminate of the disclosure comprises at least two metal layers and an insulation layer disposed between the metal layers, wherein the insulation layer is made by curing the resin composition at high temperature and high pressure to the C-stage, a suitable curing temperature being for example between 180ºC and 240° C. and preferably between 200° C. and 220° C. and a suitable curing time being 60 to 150 minutes and preferably 90 to 120 minutes. The insulation layer may be formed by curing the aforesaid prepreg or resin film to the C-stage. The metal layer comprises a metal foil or a metal plate, wherein the metal foil may comprise copper, aluminum, nickel, platinum, silver, gold or alloy thereof. For example, metal foils are used for the metal layer, and all of them are copper foils. In one embodiment, the afore-mentioned laminate is a copper-clad laminate (CCL); the metal plate may comprise copper, aluminum, nickel, platinum, silver, gold or alloys thereof; in one embodiment, for example, a metal plate is used for at least one layer of the metal layers, the metal plate being an aluminum plate, and the laminate made therefrom is an aluminum substrate.

In addition, the laminate may be further processed by trace formation processes to make a circuit board, such as a printed circuit board.

In one embodiment of making a printed circuit board, a double-sided copper-clad laminate (such as product EM-891, available from Elite Material Co., Ltd.) with a thickness of 28 mil and having 0.5 ounce (oz) HVLP (hyper very low profile) copper foils may be used, which is subject to drilling and then electroplating, so as to form electrical conduction between the top layer copper foil and the bottom layer copper foil. Then the top layer copper foil and the bottom layer copper foil are etched to form inner layer circuits. Then brown oxidation and roughening are performed on the inner layer circuits to form uneven structures on the surface to increase roughness. Next, a vacuum lamination apparatus is used to laminate the assembly of a copper foil, the prepreg, the inner layer circuit, the prepreg and a copper foil stacked in said order by heating at 190° ° C. to 220ºC for 90 to 200 minutes to cure the insulation material of the prepregs. Next, black oxidation, drilling, copper plating and other known circuit board processes are performed on the outmost copper foils so as to obtain the printed circuit board.

In one embodiment, the resin composition disclosed herein may achieve improvement in one or more of the following properties: thermal impedance, thermal conductivity, copper foil peeling strength, visible light reflectivity, routing distance and flame retardancy.

For example, in one embodiment, articles made from the resin composition disclosed herein have one, more or all of the following properties:
a thermal impedance as measured by reference to ASTM-D5470 of less than or equal to 0.0099° C.*in²/W;
a thermal conductivity as measured by reference to ASTM-D5470 of greater than or equal to 4.95 W/(m·K);
a copper foil peeling strength as measured by reference to IPC-TM-650 2.4.8 of greater than or equal to 4.89 lb/in;
a visible light reflectivity of greater than or equal to 81%;
a routing distance of greater than or equal to 292 cm; and
a flame retardancy of V-O as measured by reference to UL 94.

Raw materials below were used to prepare the resin compositions of various Examples and Comparative Examples of the present disclosure according to the amount listed in Table 1 to Table 6 and further fabricated to prepare test samples.

Materials and reagents used in the resin composition of Examples and Comparative Examples disclosed herein are listed below:
BE-188: bisphenol A epoxy resin, available from Chang Chun Plastics.
EPPN-501: triphenylmethane epoxy resin, available from Nippon Kayaku.
NC-3000: biphenyl epoxy resin, available from Nippon Kayaku.
CY-184: alicyclic epoxy resin, available from Huntsman.
BNE-200: bisphenol A novolac epoxy resin, available from Chang Chun Plastics.
PKHB: bisphenol A-based phenoxy resin, Mw-32000, available from Gabriel Performance Products.
PKHH: bisphenol A-based phenoxy resin, Mw=52000, available from Gabriel Performance Products.
YP50S: bisphenol A-based phenoxy resin, Mw=60000, available from Nippon Steel & Sumikin Chemical.
FX-293: fluorene-based phenoxy resin, Mw-45000, available from Tohto Kasei Co., Ltd.
H-TMAn: hydrogenated trimellitic anhydride, available from Mitsubishi Gas Chemical Co., Inc.
TMA: trimellitic anhydride, available from Kingyorker Enterprise Co., Ltd.
MH-700: a mixture of 4-methylhexahydrophthalic anhydride and hexahydrophthalic anhydride, having a mass ratio of 70:30, available from New Japan Chemical Co., Ltd.
TMEG-S: ethylene glycol bis(anhydrotrimellitate), available from New Japan Chemical Co., Ltd.
ABN-030: co-sintered body of aluminum nitride and boron nitride (the weight ratio of aluminum nitride and boron nitride being 6:1 to 14:1), having a particle size distribution (D50) of 20 μm to 30 μm, available from Vast Applied Material Technology Corporation.
ABN-040: co-sintered body of aluminum nitride and boron nitride (the weight ratio of aluminum nitride and boron nitride being 6:1 to 14:1), having a particle size distribution (D50) of 30 μm to 40 μm, available from Vast Applied Material Technology Corporation.
BN: boron nitride, product name CFP007ST, available from 3M.
AlN: aluminum nitride, product name AlN-010S, available from Vast Applied Material Technology Corporation.
SC-2500-SMJ: spherical silica with surface pre-treated by methacrylate silane coupling agent, available from Admatechs.
Al₂O₃: spherical aluminum oxide, available from Vast Applied Material Technology Corporation.
C11Z-CN: 1-cyanoethyl-2-undecylimidazole, available from Shikoku Chemicals Corp.
PM: propylene glycol methyl ether, commercially available.
In the Tables, Z represents the total parts by weight of epoxy resin, phenoxy resin and acid anhydride in the resin composition. For example, in Example E1, Z represents 100+20+40=160 parts by weight, and the amount of solvent in Example E1 is 160*1.1=176 parts by weight.

Compositions and test results of resin compositions of Examples and Comparative Examples are listed below (in part by weight):

TABLE 1
Resin compositions of Examples (in part by weight) and test results

| Component | Name | E1 | E2 | E3 | E4 | E5 |
|---|---|---|---|---|---|---|
| epoxy resin | BE-188 | 100 | 100 | 100 | 100 | 100 |
| | EPPN-501 | | | | | |
| | NC-3000 | | | | | |
| | CY-184 | | | | | |
| | BNE-200 | | | | | |
| phenoxy resin | PKHB | 20 | 10 | 30 | 20 | 20 |
| | PKHH | | | | | |
| | YP50S | | | | | |
| | FX-293 | | | | | |
| acid anhydride | H-TMAn | 40 | 40 | 40 | 30 | 50 |
| | TMA | | | | | |
| | MH-700 | | | | | |
| | TMEG-S | | | | | |
| filler | ABN-030 | 300 | 300 | 300 | 300 | 300 |
| | ABN-040 | | | | | |
| | BN | | | | | |
| | AlN | | | | | |
| | SC-2500-SMJ | | | | | |
| | Al₂O₃ | | | | | |
| curing accelerator | C11Z-CN | 0.1 | 0.1 | 0.1 | 0.1 | 0.1 |
| solvent | PM | Z*1.1 | Z*1.1 | Z*1.1 | Z*1.1 | Z*1.1 |
| Property | Unit | E1 | E2 | E3 | E4 | E5 |
| thermal impedance | ° C.*in²/W | 0.0097 | 0.0094 | 0.0099 | 0.0097 | 0.0098 |
| thermal conductivity | W/(m · K) | 5.05 | 5.11 | 5.01 | 5.06 | 5.03 |
| copper foil peeling strength (1 oz) | lb/in | 5.18 | 5.15 | 5.31 | 5.02 | 5.21 |
| visible light reflectivity | % | 84 | 85 | 85 | 81 | 85 |
| routing distance | cm | 293 | 293 | 294 | 292 | 295 |
| flame retardancy | none | V-0 | V-0 | V-0 | V-0 | V-0 |

TABLE 2
Resin compositions of Examples (in part by weight) and test results

| Component | Name | E6 | E7 | E8 | E9 | E10 |
|---|---|---|---|---|---|---|
| epoxy resin | BE-188 | 100 | 100 | | | |
| | EPPN-501 | | | | | 50 |
| | NC-3000 | | | 100 | | |
| | CY-184 | | | | | 50 |
| | BNE-200 | | | | 100 | |
| phenoxy resin | PKHB | 20 | 20 | 20 | 20 | 20 |
| | PKHH | | | | | |
| | YP50S | | | | | |
| | FX-293 | | | | | |
| acid anhydride | H-TMAn | 40 | 40 | 40 | 40 | 40 |
| | TMA | | | | | |
| | MH-700 | | | | | |
| | TMEG-S | | | | | |
| filler | ABN-030 | 250 | 400 | 300 | 300 | 300 |
| | ABN-040 | | | | | |
| | BN | | | | | |
| | AlN | | | | | |
| | SC-2500-SMJ | | | | | |
| | Al₂O₃ | | | | | |
| curing accelerator | C11Z-CN | 0.1 | 0.1 | 0.1 | 0.1 | 0.1 |
| solvent | PM | Z*1.1 | Z*1.1 | Z*1.1 | Z*1.1 | Z*1.1 |
| Property | Unit | E6 | E7 | E8 | E9 | E10 |
| thermal impedance | ° C.*in²/W | 0.0099 | 0.0092 | 0.0093 | 0.0092 | 0.0092 |
| thermal conductivity | W/(m · K) | 4.95 | 5.24 | 5.20 | 5.21 | 5.25 |
| copper foil peeling strength (1 oz) | lb/in | 5.27 | 5.01 | 5.25 | 4.89 | 5.12 |
| visible light reflectivity | % | 82 | 85 | 84 | 84 | 84 |
| routing distance | cm | 294 | 292 | 294 | 292 | 292 |
| flame retardancy | none | V-0 | V-0 | V-0 | V-0 | V-0 |

TABLE 3
Resin compositions of Examples (in part by weight) and test results

| Component | Name | E11 | E12 | E13 | E14 | E15 |
|---|---|---|---|---|---|---|
| epoxy resin | BE-188 | 100 | 100 | 100 | 30 | 20 |
| | EPPN-501 | | | | | |
| | NC-3000 | | | | 20 | 10 |
| | CY-184 | | | | 15 | 20 |
| | BNE-200 | | | | 35 | 50 |
| phenoxy resin | PKHB | 5 | | 20 | | 25 |
| | PKHH | 5 | | | 15 | |
| | YP50S | 10 | 5 | | 10 | |
| | FX-293 | | 15 | | | |
| acid anhydride | H-TMAn | 40 | 40 | 40 | 45 | 45 |
| | TMA | | | | | |
| | MH-700 | | | | | |
| | TMEG-S | | | | | |
| filler | ABN-030 | 300 | 300 | | 250 | 100 |
| | ABN-040 | | | 300 | 100 | 250 |
| | BN | | | | | |
| | AlN | | | | | |
| | SC-2500-SMJ | | | | | |
| | Al₂O₃ | | | | | |
| curing accelerator | C11Z-CN | 0.1 | 0.1 | 0.1 | 0.05 | 0.2 |
| solvent | PM | Z*1.1 | Z*1.1 | Z*1.1 | Z*1.0 | Z*1.5 |
| Property | Unit | E11 | E12 | E13 | E14 | E15 |
| thermal impedance | ° C.*in²/W | 0.0097 | 0.0097 | 0.0097 | 0.0087 | 0.0088 |
| thermal conductivity | W/(m · K) | 5.05 | 5.06 | 5.06 | 6.01 | 6.02 |
| copper foil peeling strength (1 oz) | lb/in | 5.18 | 5.24 | 5.04 | 5.30 | 5.32 |
| visible light reflectivity | % | 84 | 84 | 84 | 85 | 85 |
| routing distance | cm | 293 | 293 | 293 | 296 | 297 |
| flame retardancy | none | V-0 | V-0 | V-0 | V-0 | V-0 |

TABLE 4
Resin compositions of Comparative Examples (in part by weight) and test results

| Component | Name | C1 | C2 | C3 | C4 | C5 |
|---|---|---|---|---|---|---|
| epoxy resin | BE-188 | 100 | 100 | 100 | 100 | 100 |
| | EPPN-501 | | | | | |
| | NC-3000 | | | | | |
| | CY-184 | | | | | |
| | BNE-200 | | | | | |
| phenoxy resin | PKHB | 20 | 20 | 20 | 20 | 20 |
| | PKHH | | | | | |
| | YP50S | | | | | |
| | FX-293 | | | | | |
| acid anhydride | H-TMAn | | | | 40 | 40 |
| | TMA | 40 | | | | |
| | MH-700 | | 40 | | | |
| | TMEG-S | | | 40 | | |
| filler | ABN-030 | 300 | 300 | 300 | | |
| | ABN-040 | | | | | |
| | BN | | | | 100 | |
| | AlN | | | | 200 | |
| | SC-2500-SMJ | | | | | 300 |
| | Al₂O₃ | | | | | |
| curing accelerator | C11Z-CN | 0.1 | 0.1 | 0.1 | 0.1 | 0.1 |
| solvent | PM | Z*1.1 | Z*1.1 | Z*1.1 | Z*1.1 | Z*1.1 |
| Property | Unit | C1 | C2 | C3 | C4 | C5 |
| thermal impedance | ° C.*in²/W | 0.0098 | 0.0121 | 0.0121 | 0.0098 | 0.0140 |
| thermal conductivity | W/(m · K) | 5.04 | 4.97 | 4.86 | 5.05 | 0.46 |
| copper foil peeling strength (1 oz) | lb/in | 4.52 | 4.25 | 4.25 | 3.25 | 4.65 |
| visible light reflectivity | % | 53 | 66 | 63 | 85 | 66 |
| routing distance | cm | 274 | 296 | 282 | 260 | 310 |
| flame retardancy | none | V-0 | V-0 | V-0 | V-0 | V-0 |

TABLE 5
Resin compositions of Comparative Examples (in part by weight) and test results

| Component | Name | C6 | C7 | C8 | C9 | C10 |
|---|---|---|---|---|---|---|
| epoxy resin | BE-188 | 100 | 100 | 100 | 100 | 100 |
| | EPPN-501 | | | | | |
| | NC-3000 | | | | | |
| | CY-184 | | | | | |
| | BNE-200 | | | | | |
| phenoxy resin | PKHB | 20 | 20 | 20 | 20 | 20 |
| | PKHH | | | | | |
| | YP50S | | | | | |
| | FX-293 | | | | | |
| acid anhydride | H-TMAn | 40 | 10 | 80 | 40 | 40 |
| | TMA | | | | | |
| | MH-700 | | | | | |
| | TMEG-S | | | | | |
| filler | ABN-030 | | 300 | 300 | 200 | 700 |
| | ABN-040 | | | | | |
| | BN | | | | | |
| | AlN | | | | | |
| | SC-2500-SMJ | | | | | |
| | Al₂O₃ | 300 | | | | |
| curing accelerator | C11Z-CN | 0.1 | 0.1 | 0.1 | 0.1 | 0.1 |
| solvent | PM | Z*1.1 | Z*1.1 | Z*1.1 | Z*1.1 | Z*1.1 |
| Property | Unit | C6 | C7 | C8 | C9 | C10 |
| thermal impedance | C*in²/W | 0.0131 | 0.0091 | 0.0100 | 0.0116 | 0.0085 |
| thermal conductivity | W/(m · K) | 1.50 | 5.28 | 5.00 | 3.25 | 6.19 |
| copper foil peeling strength (1 oz) | lb/in | 4.25 | 3.05 | 3.85 | 4.85 | 2.75 |
| visible light reflectivity | % | 86 | 49 | 89 | 81 | 86 |
| routing distance | cm | 257 | 302 | 291 | 314 | 259 |
| flame retardancy | none | V-0 | V-0 | V-1 | V-1 | V-0 |

TABLE 6
Resin compositions of Comparative Examples
(in part by weight) and test results

| Component | Name | C11 | C12 | C13 |
|---|---|---|---|---|
| epoxy resin | BE-188 | 100 | 100 | 100 |
| | EPPN-501 | | | |
| | NC-3000 | | | |
| | CY-184 | | | |
| | BNE-200 | | | |
| phenoxy resin | PKHB | | | |
| | PKHH | | | |
| | YP50S | | | |
| | FX-293 | | | |
| acid anhydride | H-TMAn | 40 | | 40 |
| | TMA | | 40 | |
| | MH-700 | | | |
| | TMEG-S | | | |
| filler | ABN-030 | 300 | 300 | |
| | ABN-040 | | | |
| | BN | | | |
| | AlN | | | |
| | SC-2500-SMJ | | | 300 |
| | Al₂O₃ | | | |
| curing accelerator | C11Z-CN | 0.1 | 0.1 | 0.1 |
| solvent | PM | Z*1.1 | Z*1.1 | Z*1.1 |
| Property | Unit | C11 | C12 | C13 |
| thermal impedance | ° C.*in²/W | 0.0097 | 0.0097 | 0.0145 |
| thermal conductivity | W/(m · K) | 5.06 | 5.05 | 0.67 |
| copper foil peeling | lb/in | 1.85 | 1.85 | 3.96 |
| strength (1 oz) | | | | |
| visible light | % | 84 | 58 | 70 |
| reflectivity | | | | |
| routing distance | cm | 260 | 258 | 300 |
| flame retardancy | none | V-0 | V-0 | V-0 |

Samples (specimens) for the properties measured above were prepared as described below and tested and analyzed under specified conditions below.

1. Resin film:
Resin composition (in part by weight) from each Example or each Comparative Example was individually added to a stirred tank and well-mixed to form a varnish, which was coated on a polyethylene terephthalate film (PET film, with a thickness of 50 μm) to uniformly adhere the resin composition thereon, followed by heating and baking at 100° ° C. for 3 minutes to obtain each thin film. After that, the PET film was removed to obtain a resin film with a thickness of 100 μm.

2. Aluminum substrate:
One 1 oz high temperature elongation (HTE) copper foil, one 1.5 mm aluminum plate and one aforesaid resin film were prepared and stacked in the order of an aluminum plate, a resin film and a copper foil, followed by lamination under vacuum at 250 psi to 600 psi and 200° ° C. to 220ºC for 90 minutes to 120 minutes to form the aluminum substrate, wherein the cured resin film forms the insulation layer between the aluminum plate and the copper foil.

3. Aluminum-free substrate:
Each aluminum substrate obtained above was etched to remove the aluminum plate and the copper foil on both sides so as to obtain the aluminum-free substrate.

For each sample, test items and test methods are described below:

### Thermal Impedance

The aluminum-free substrate sample with a size of 50 mm*50 mm*25.4 mm was tested by a thermal impedance measurement instrument (model No. LW-9091 ir, available from Long Win Science and Technology Corporation) during the measurement of thermal impedance by reference to ASTM-D5470. The unit of thermal impedance is ° C.*in²/W. In the technical field to which the present disclosure pertains, lower thermal impedance is better, and a difference in thermal impedance of greater than or equal to 0.0010° C.*in²/W represents a substantial difference (i.e., significant technical difficulty) in thermal impedance in different materials.

### Thermal Conductivity (Tk)

The aforesaid aluminum-free substrate sample with a size of 50 mm*50 mm*25.4 mm was tested by reference to the processes described in ASTM-D5470. The sample was heated by a test apparatus from room temperature (about 25° C.), and after 30 minutes of heating when the temperature was 80° ° C., a thermal impedance measurement instrument (model No. LW-9091 ir, available from Long Win Science and Technology Corporation) was used to calculate and analyze to obtain the thermal conductivity. The unit of thermal conductivity is W/(m·K). In the technical field to which the present disclosure pertains, higher thermal conductivity is better, representing that the material is more thermally conductive. A difference in thermal conductivity of greater than or equal to 0.5 W/(m·K) represents a significant difference (i.e., significant technical difficulty) in thermal conductivity in different materials.

### Copper Foil Peeling Strength (1 Ounce, 1 Oz Peeling Strength, 1 Oz P/S)

The aforesaid aluminum substrate was cut into a rectangular sample with a width of 24 mm and a length of greater than 60 mm, which was etched to remove surface copper foil to leave a rectangular copper foil with a width of 3.18 mm and a length of greater than 60 mm, and tested by using a tensile strength tester by reference to IPC-TM-650 2.4.8 at room temperature (about 25ºC) to measure the force (lb/in) required to separate the 1 ounce copper foil from the insulation layer of the substrate. In the technical field to which the present disclosure pertains, higher copper foil peeling strength is better. A difference in copper foil peeling strength of greater than or equal to 0.5 lb/in represents a substantial difference (i.e., significant technical difficulty) in copper foil peeling strength in different laminates.

### Visible Light Reflectivity (VL Reflectivity)

The aluminum-free substrate sample with a size of 50 mm*50 mm*25.4 mm was tested by a spectrophotometer (manufactured by KONICA MINOLTA Co., Ltd., model No. CM-2600d) during the measurement of visible light reflectivity (wavelength range from 360 nm to 830 nm). In the technical field to which the present disclosure pertains, higher visible light reflectivity is better. A difference in visible light reflectivity of greater than or equal to 10% represents a substantial difference (i.e., significant technical difficulty) in different materials.

### Routing Distance

The aforesaid aluminum substrate sample (with a size of 18 inches in length and 16 inches in width) was tested by a numerical control forming machine (routing machine, model No. TQZX-II) and was milled by a milling cutter with a diameter of 1.6 mm (product name: DCR-1700) based on the designed patterns. After the milling cutter was broke, the milling process was stopped, and the total travel length along the patterns before the milling cutter broke was measured (in cm). In the technical field to which the present disclosure pertains, longer routing distance is better, which represents higher wear resistance against a milling cutter and lower costs of consumables. A difference in routing distance of greater than or equal to 30 cm represents a substantial difference (i.e., significant technical difficulty) in routing distance in different laminates.

### Flame Retardancy

The aluminum-free substrate sample was subjected to the measurement. The flame retardancy test was performed in accordance with the UL 94 rating, and the results were represented by V-0, V-1, or V-2, wherein V-0 indicates a superior flame retardancy to V-1, and V-1 indicates a superior flame retardancy to V-2. The following observations can be made according to the test results above.

A side-by-side comparison of Example E1 and Comparative Examples C1-C3 indicates that the resin composition containing hydrogenated trimellitic anhydride (i.e., Example E1), in contrast to the resin composition containing other anhydrides (i.e., Comparative Examples C1-C3), may achieve significant improvements in at least one of the following properties: thermal impedance, copper foil peeling strength (1 oz) and visible light reflectivity.

A side-by-side comparison of Example E1 and Comparative Examples C4-C6 indicates that the resin composition containing a co-sintered body of aluminum nitride and boron nitride (i.e., Example E1), in contrast to the resin composition containing other fillers (i.e., Comparative Examples C4-C6), may achieve significant improvements in at least one of the following properties: thermal impedance, thermal conductivity, copper foil peeling strength (1 oz), visible light reflectivity and routing distance.

A side-by-side comparison of Examples E4-E5 and Comparative Examples C7-C8 indicates that the resin composition containing 30 to 50 parts by weight of hydrogenated trimellitic anhydride (i.e., Examples E4-E5), in contrast to the resin composition containing hydrogenated trimellitic anhydride outside the range of 30 to 50 parts by weight (i.e., Comparative Examples C7-C8), may achieve significant improvements in at least one of the following properties: copper foil peeling strength (1 oz), visible light reflectivity and flame retardancy.

A side-by-side comparison of Examples E6-E7 and Comparative Examples C9-C10 indicates that the resin composition containing 250 to 400 parts by weight of a co-sintered body of aluminum nitride and boron nitride (i.e., Examples E6-E7), in contrast to the resin composition containing a co-sintered body of aluminum nitride and boron nitride outside the range of 250 to 400 parts by weight (i.e., Comparative Examples C9-C10), may achieve significant improvements in at least one of the following properties: thermal impedance, thermal conductivity, copper foil peeling strength (1 oz), routing distance and flame retardancy.

Compared with Examples E1-E15, the resin composition of Comparative Example C11 does not contain a phenoxy resin, and the results indicate that significant improvements in properties including copper foil peeling strength (1 oz) and routing distance cannot be achieved.

Compared with Examples E1-E15, the resin composition of Comparative Example C12, not containing a phenoxy resin and containing trimellitic anhydride instead of hydrogenated trimellitic anhydride, fails to achieve significant improvements in properties including copper foil peeling strength (1 oz), visible light reflectivity and routing distance.

Compared with Examples E1-E15, the resin composition of Comparative Example C13, not containing a phenoxy resin and containing silica instead of a co-sintered body of aluminum nitride and boron nitride as a filler, fails to achieve significant improvements in properties including thermal impedance, thermal conductivity, copper foil peeling strength (1 oz) and visible light reflectivity.

Overall, the resin composition of the present disclosure can achieve at the same time desirable properties including a visible light reflectivity of greater than or equal to 81%, a routing distance of greater than or equal to 292 cm, a flame retardancy of V-O as measured by reference to UL 94 and a copper foil peeling strength as measured by reference to IPC-TM-650 2.4.8 of greater than or equal to 4.89 lb/in.

The above detailed description is merely illustrative in nature and is not intended to limit the embodiments of the subject matter or the application and use of such embodiments. As used herein, the term “exemplary” means “serving as an example, instance, or illustration.” Any implementation described herein as exemplary is not necessarily to be construed as preferred or advantageous over other implementations.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments. Also, various changes can be made in the function and arrangement of elements without departing from the scope defined by the claims, which include known equivalents and foreseeable equivalents at the time of filing this patent application.

What is claimed is:

1. A resin composition, comprising:
(A) 100 parts by weight of an epoxy resin;
(B) 10 to 30 parts by weight of a phenoxy resin;
(C) 30 to 50 parts by weight of hydrogenated trimellitic anhydride; and
(D) 250 to 400 parts by weight of a co-sintered body of aluminum nitride and boron nitride.

2. The resin composition of claim 1, wherein the epoxy resin comprises bisphenol A epoxy resin, triphenylmethane epoxy resin, biphenyl epoxy resin, alicyclic epoxy resin or a combination thereof.

3. The resin composition of claim 1, wherein the phenoxy resin comprises bisphenol A-based phenoxy resin, fluorene-based phenoxy resin or a combination thereof.

4. The resin composition of claim 1, wherein the weight ratio of aluminum nitride to boron nitride in the co-sintered body of aluminum nitride and boron nitride is 6:1 to 14:1.

5. The resin composition of claim 1, wherein the co-sintered body of aluminum nitride and boron nitride has a particle size distribution (D50) of 20 μm to 40 μm.

6. The resin composition of claim 1, further comprising curing accelerator, flame retardant, polymerization inhibitor, solvent, silane coupling agent, coloring agent, toughening agent or a combination thereof.

7. An article made from the resin composition of claim 1, comprising a prepreg, a resin film, a laminate or a printed circuit board.

8. The article of claim 7, having a visible light reflectivity of greater than or equal to 81%.

9. The article of claim 7, having a routing distance of greater than or equal to 292 cm.

10. The article of claim 7, having a flame retardancy of V-0 as measured by reference to UL 94.

11. The article of claim 7, having a copper foil peeling strength as measured by reference to IPC-TM-650 2.4.8 of greater than or equal to 4.89 lb/in.
